(19) United States
(12) Patent Application Publication
(10) Pub. No.: US 2014/0132322 A1
(43) Pub. Date: May 15, 2014

(54) INPUT CIRCUIT

(71) Applicant: Fujitsu Semiconductor Limited, Yokohama-shi (JP)

(72) Inventor: Osamu UNO, Kasugai (JP)

(73) Assignee: Fujitsu Semiconductor Limited, Yokohama-shi (JP)

(21) Appl. No.: 14/075,633

(22) Filed: Nov. 8, 2013

(30) Foreign Application Priority Data
Nov. 13, 2012 (JP) 2012-249182

(51) Int. Cl. H03K 3/3565; H03K 3/013

(52) U.S. Cl. CPC H03K 3/3565; H03K 3/013
USPC 327/206

(57) ABSTRACT

An input circuit includes a first P-channel MOS transistor including a first terminal supplied with a high-potential power supply voltage and a second terminal coupled to a first node, a second P-channel MOS transistor including a first terminal coupled to the first node and a second terminal coupled to a second node, a first N-channel MOS transistor including a first terminal coupled to the second node and a second terminal coupled to a third node, and a second N-channel MOS transistor including a first terminal coupled to the third node and a second terminal supplied with a low-potential power supply voltage. An input signal is supplied to gate terminals of the P-channel MOS transistors and the N-channel MOS transistors. A control circuit controls the potential at the first node and the potential at the third node based on the input signal and the potential at the second node.

### CROSS-REFERENCE TO RELATED APPLICATIONS

This application is based upon and claims the benefit of priority from prior Japanese Patent Application No. 2012-249182, filed on Nov. 13, 2012, the entire contents of which are incorporated herein by reference.

### FIELD

This disclosure relates to an input circuit.

### BACKGROUND

Semiconductor integrated circuit devices recently employ CMOS (Complementary Metal Oxide Semiconductor) Schmitt input circuits to reduce noises superimposed on an input signal. Japanese Laid-Open Patent Publication No. 06-053783 and Japanese Laid-Open Patent Publication No. 2001-185996 disclose examples of Schmitt input circuits. FIG. 7 illustrates a Schmitt input circuit 30 in a related art.

As illustrated in FIG. 7, an input circuit 30 includes an inverter circuit 31, an inverter circuit 32 for receiving an output signal from the inverter circuit 31, and a hysteresis setting circuit 33 for providing a hysteresis characteristic.

The inverter circuit 31 includes transistors TP11, TP12, TN11 and TN12 coupled in series between power lines L1 and L2. The power line L1 is supplied with a high-potential power supply voltage VDD, while the power line L2 is supplied with a low-potential power supply voltage VSS. The transistors TP11 and TP12 are P-channel MOS transistors, while the transistors TN11 and TN12 are N-channel MOS transistors. The gate terminals of the transistors TP11, TP12, TN11 and TN12 are coupled to an input terminal Ti supplied with an input signal Vin. A node N11 between the transistors TP12 and TN11, which functions as an output terminal of the inverter circuit 31, is coupled to an input terminal of the inverter circuit 32. An output terminal of the inverter circuit 32, at which an output signal Vo is output, is coupled to an output terminal To.

The hysteresis setting circuit 33 includes a P-channel MOS transistor TP13 and an N-channel MOS transistor TN13. The source terminal of the transistor TP13 is coupled to a node N12 between the transistors TP11 and TP12. The drain terminal of the transistor TP13 is coupled to the power line L2. The source terminal of the transistor TN13 is coupled to a node N13 between the transistors TN11 and TN12. The drain terminal of the transistor TN13 is coupled to the power line L1. The gate terminals of the transistors TP13 and TN13 are coupled to the node N11 between the transistors TP12 and TN11, that is, to the output terminal of the inverter circuit 31.

Next, an operation of the input circuit 30 will now be described.

When the input signal Vin is at an L level (e.g., at the level of the low-potential power supply voltage VSS), the transistors TP11 and TP12 are activated, while the transistors TN11 and TN12 are inactivated. As a result, the potential at the node N11 is set at an H level (e.g., at the level of the high-potential power supply voltage VDD). This causes the inverter circuit 32 to output an output signal Vo of the L level. At this time, the transistor TN13 is in an activated state as the gate signal is at the H level.

When the input signal Vin transits from the L level to the H level, the transistors TP11, TP12, TN11 and TN12 switch between activated and inactivated states. When the voltage value of the input signal Vin increases to activate the transistors TN11 and TN12, a voltage divided by the transistors TN12 and TN13 appears at the node N13 as the transistor TN13 is in the activated state. Thus, the voltage at the node N13 does not decrease to the level of the low-potential power supply voltage VSS. The ON-resistance of the transistor TN13 thus serves to suppress a decrease in the potential at the node N13. A threshold voltage VIH of the input circuit 30 at the rise of the input signal Vin is therefore higher than the threshold voltage (e.g., about (VDD+VSS)/2) in the case of an absence of the transistor TN13.

When the input signal Vin is at the H level, the transistors TP11 and TP12 are inactivated, while the transistors TN11 and TN12 are activated. As a result, the potential at the node N11 is set at the L level. This causes the inverter circuit 32 to output an output signal Vo of the H level. At this time, the transistor TP13 is in the activated state as the gate signal is at the L level.

When the input signal Vin transits from the H level to the L level, the transistors TP11, TP12, TN11 and TN12 switch between activated and inactivated states. When the voltage value of the input signal Vin decreases to activate the transistors TP11 and TP12, a voltage divided by the transistors TP11 and TP13 appears at the node N12 as the transistor TP13 is in the activated state. Thus, the voltage at the node N12 does not increase to the level of the high-potential power supply voltage VDD. The ON-resistance of the transistor TP13 thus serves to suppress an increase in the potential at the node N12. A threshold voltage VIL of the input circuit 30 at the fall of the input signal Vin is therefore lower than the threshold voltage (e.g., about (VDD+VSS)/2) in the case of an absence of the transistor TP13.

In this manner, the hysteresis setting circuit 33 sets the different threshold voltages VIH and VIL due to the functions of the transistors TN13 and TP13. This provides a hysteretic transfer characteristic to the input circuit 30.

In the Schmitt input circuit 30 described above, the smaller the amplitude of the input signal Vin, the longer the signal propagation delay time becomes, due to the characteristics of CMOS. FIG. 8A illustrates a signal propagation delay time Td1 when the input signal Vin has an amplitude (full amplitude) from the high-potential power supply voltage VDD to the low-potential power supply voltage VSS. FIG. 8B illustrates a signal propagation delay time Td2 when the input signal Vin has an amplitude between the threshold voltages VIH and VIL of the input circuit 30. As illustrated in FIGS. 8A and 8B, the propagation delay time Td2 when the amplitude of the input signal Vin is small is longer than the propagation delay time Td1 when the amplitude of the input signal Vin is large. The reason for such an increase in the propagation delay time Td2 when the amplitude of the input signal Vin is small will now described below.

When the input signal Vin transits from the L level (of the voltage VIL) to the H level (of the voltage VIH) and the gate voltages of the transistors TN11 and TN12 increase to near the threshold voltage VIH, the hysteresis characteristic maintains the voltage at the node N11 at the level of the high-potential power supply voltage VDD for a while. At this time, since the voltage VIH is lower than the high-potential power supply voltage VDD, the gate voltage of the transistor TN11 is also lower than its drain voltage (or source voltage). Thus, the transistor TN11 is not immediately activated. That is, the time until the voltage at the node N11 decreases to the low-potential power supply voltage VSS is long. This causes a delay in the timing of switching of the transistor TN13 to an inactivated state. This results in that the voltage at the node N13 does not decrease due to the ON-resistance of the transistor TN13. Therefore, the transistor TN11 is not immediately activated. Accordingly, the signal propagation delay time significantly increases compared to the case where the input signal Vin has a full amplitude. Setting the threshold voltage VIH to a lower level and the threshold voltage VIL to a higher level, that is, setting the potential difference between the voltages VIH and VIL smaller than the amplitude of the input signal Vin may suppress an increase in the signal propagation delay time. However, a hysteresis Vhys (see FIG. 7) and therefore the noise tolerance would decrease.

### SUMMARY

One aspect of this disclosure is an input circuit. The input circuit includes first and second P-channel MOS transistors, first and second N-channel MOS transistors, and a control circuit. The first P-channel MOS transistor includes a first terminal coupled to a first power line that is supplied with a high-potential power supply voltage, a second terminal coupled to a first node, and a gate terminal that receives an input signal. The second P-channel MOS transistor includes a first terminal coupled to the first node, a second terminal coupled to a second node, and a gate terminal that receives the input signal. The first N-channel MOS transistor includes a first terminal coupled to the second node, a second terminal coupled to a third node, and a gate terminal that receives the input signal. The second N-channel MOS transistor includes a first terminal coupled to the third node, a second terminal coupled to a second power line that is supplied with a low-potential power supply voltage lower than the high-potential power supply voltage, and a gate terminal that receives the input signal. The control circuit controls the potential at the first node and the potential at the third node based on the input signal and the potential at the second node.

Additional objects and advantages of the invention will be set forth in part in the description which follows, and in part will be obvious from the description, or may be learned by practice of the invention. The objects and advantages of the invention will be realized and attained by means of the elements and combinations particularly pointed out in the appended claims.

It is to be understood that both the foregoing general description and the following detailed description are exemplary and explanatory and are not restrictive of the invention, as claimed.

### BRIEF DESCRIPTION OF THE DRAWINGS

The embodiment, together with objects and advantages thereof, may best be understood by reference to the following description of the presently preferred embodiments together with the accompanying drawings in which:

FIG. 1 is a schematic circuit diagram of an input circuit according to a first embodiment;

FIG. 2 is a schematic waveform diagram illustrating an operation of the input circuit illustrated in FIG. 1;

FIGS. 3A and 3B are graphs illustrating the relationship between the amplitude of an input signal and the signal propagation delay time;

FIG. 4 is a schematic circuit diagram of an input circuit according to a second embodiment;

FIG. 5 is a schematic waveform diagram illustrating an operation of the input circuit illustrated in FIG. 4;

FIG. 6 is a graph illustrating the relationship between the input signal and the through-current;

FIG. 7 is a schematic circuit diagram of an input circuit in a related art; and

FIGS. 8A and 8B are illustrative views illustrating the relationship between the amplitude of an input signal and the signal propagation delay time.

### DESCRIPTION OF THE EMBODIMENTS

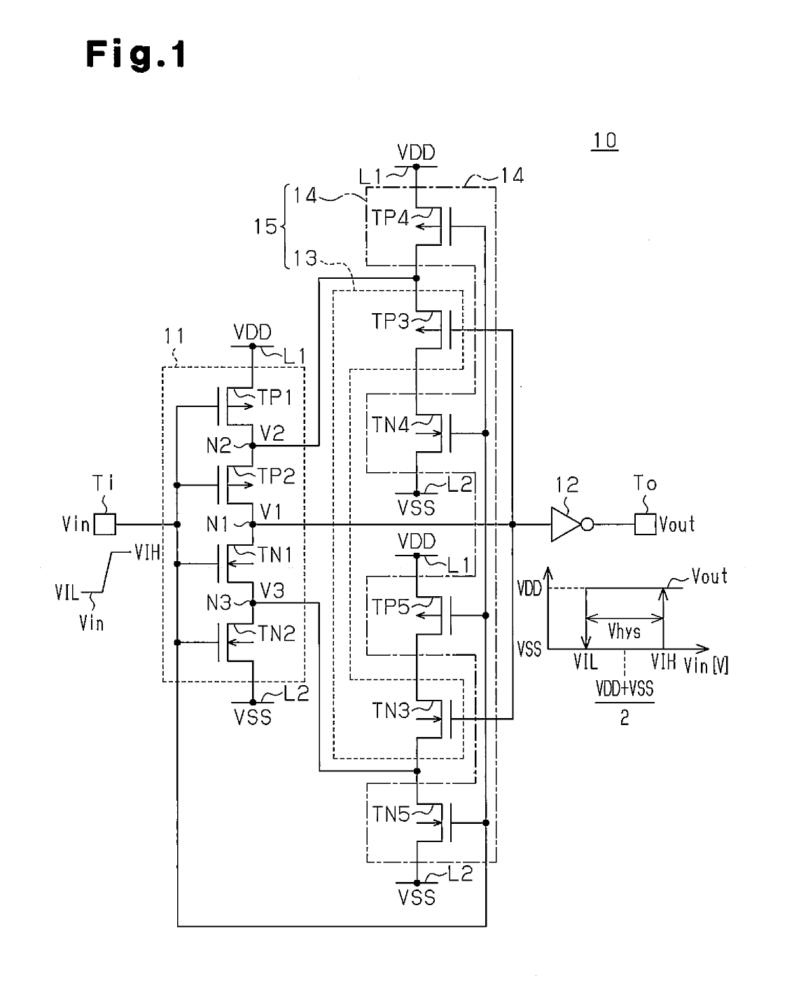

A first embodiment will now be described with reference to FIGS. 1 to 3B.

FIG. 1 illustrates an input circuit 10 which is a CMOS Schmitt input circuit. The input circuit 10 operates based on a threshold voltage VIH at the rise of an input signal Vin and operates based on a threshold voltage VIL at the fall of the input signal Vin. The input circuit 10 has a hysteresis characteristic which is set such that the threshold voltage VIH is higher than the threshold voltage VIL. The input circuit 10 includes an inverter circuit 11, which receives the input signal Vin, and an inverter circuit 12, which inversely amplifies an output signal from the inverter circuit 11. The input circuit 10 also includes a control circuit 15. The control circuit 15 includes a hysteresis setting circuit 13, which defines a hysteresis characteristic (a hysteresis Vhys), and a hysteresis deactivation circuit 14. The hysteresis deactivation circuit 14 deactivates the hysteresis setting circuit 13 when the input signal Vin exceeds a given threshold value.

The inverter circuit 11 inversely amplifies the input signal Vin, which is supplied from an internal circuit (not illustrated) of the semiconductor device to an input terminal Ti, to generate an output signal V1. The output signal V1 is then supplied to the inverter circuit 12. The input signal Vin has an amplitude from the threshold voltage VIL to the threshold voltage VIH, that is, an amplitude smaller than the full amplitude. The output signal V1 of the inverter circuit 11 has the level of a high-potential power supply voltage VDD or a low-potential power supply voltage VSS. When receiving the input signal Vin of the level of the voltage VIL, the inverter circuit 11 generates the output signal V1 of the level of the high-potential power supply voltage VDD. When receiving the input signal Vin of the level of the voltage VIH, the inverter circuit 11 generates the output signal V1 of the level of the low-potential power supply voltage VSS. For the sake of descriptive convenience, the level of the high-potential power supply voltage VDD, the level of the voltage VIH, the level of the low-potential power supply voltage VSS, and the level of the voltage VIL will hereinafter be referred to, respectively, also as “VDD level,”“VIH level,”“VSS level” and “VIL level.”

The inverter circuit 11 includes transistors TP1, TP2, TN1 and TN2 coupled in series between power lines L1 and L2. The power line L1 is supplied with the high-potential power supply voltage VDD. The power line L2 is supplied with the low-potential power supply voltage VSS, which is lower than the high-potential power supply voltage VDD. The transistors TP1 and TP2 are P-channel MOS transistors, while the transistors TN1 and TN2 are N-channel MOS transistors. The high-potential power supply voltage VDD is, for example, 5V and the low-potential power supply voltage VSS is, for example, 0V.

The transistor TP1 includes a first terminal (e.g., a source terminal) coupled to the power line L1, a second terminal (e.g., a drain terminal), and a control terminal (a gate terminal). The transistor TP2 includes a first terminal (e.g., a source terminal) coupled to the second terminal of the transistor TP1, a second terminal (e.g., a drain terminal), and a control terminal (a gate terminal). The transistor TN1 includes a first terminal (e.g., a drain terminal) coupled to the second terminal of the transistor TP2, a second terminal (e.g., a source terminal), and a control terminal (a gate terminal). The transistor TN2 includes a first terminal (e.g., a drain terminal) coupled to the second terminal of the transistor TN1, a second terminal (e.g., a source terminal) coupled to the power line L2, and a control terminal (a gate terminal).

The control terminals of the transistors TP1, TP2, TN1 and TN2 are coupled to the input terminal Ti. A node N1 between the transistors TP2 and TN1, which functions as an output terminal of the inverter circuit 11, is coupled to an input terminal of the inverter circuit 12.

The output terminal of the inverter circuit 12 is coupled to an output terminal To of the input circuit 10. The inverter circuit 12 inversely amplifies the output signal V1 of the inverter circuit 11 (voltage at the node N1) with a given gain (“1” in this example) to generate an output signal Vout. The output signal Vout is then supplied to, for example, the internal circuit (not illustrated) of the semiconductor device through the output terminal To. The output signal V1 will hereinafter be referred to also as the voltage V1 at the node N1.

The control circuit 15 controls a voltage V2 at a node N2 between the transistors TP1 and TP2 and a voltage V3 at a node N3 between the transistors TN1 and TN2 based on the input signal Vin and the voltage V1 at the node N1. The hysteresis setting circuit 13 includes a P-channel MOS transistor TP3 and an N-channel MOS transistor TN3. The deactivation circuit 14 includes P-channel MOS transistors TP4 and TP5 and N-channel MOS transistors TN4 and TN5.

In the hysteresis setting circuit 13, the transistor TP3 includes a first terminal (e.g., a source terminal), which is coupled to the node N2 and also coupled to the power line L1 via the transistor TP4, and a second terminal (e.g., a drain terminal), which is coupled to the power line L2 via the transistor TN4.

The transistor TN3 includes a first terminal (e.g., a source terminal), which is coupled to the node N3 and also coupled to the power line L2 via the transistor TN5, and a second terminal (e.g., a drain terminal), which is coupled to the power line L1 via the transistor TP5.

The transistors TP3 and TN3 set the hysteresis Vhys of the input circuit 10 by feeding the output signal V1 of the inverter circuit 11 back to the nodes N2 and N3. The transistor TP3, which feeds the output signal V1 back to the node N2, suppresses an increase in the voltage V2 at the node N2 (i.e., the source voltage of the transistor TP2) at the fall of the input signal Vin. Thus, the transistor TP3 sets the threshold voltage VIL of the input circuit 10 to be lower than the threshold voltage (e.g., about (VDD+VSS)/2) in the case of an absence of the transistor TP3. On the other hand, the transistor TN3, which feeds the output signal V1 back to the node N3, suppresses a decrease in the voltage V3 at the node N3 (i.e., the source voltage of the transistor TN2) at the rise of the input signal Vin. Thus, the transistor TN3 sets the threshold voltage VIH of the input circuit 10 to be higher than the threshold voltage (e.g., about (VDD+VSS)/2) in the case of an absence of the transistor TN3.

In the deactivation circuit 14, the transistor TP4 includes a first terminal (e.g., a source terminal) coupled to the power line L1, a second terminal (e.g., a drain terminal) coupled to the first terminal of the transistor TP3 (i.e., the node N2), and a control terminal (a gate terminal). That is, the transistor TP4 is arranged between the transistor TP3 and the power line L1. The transistor TN4 includes a first terminal (e.g., a drain terminal) coupled to the second terminal of the transistor TP3, a second terminal (e.g., a source terminal) coupled to the power line L2, and a control terminal (a gate terminal). That is, the transistor TN4 is arranged between the transistor TP3 and the power line L2.

The transistor TP5 includes a first terminal (e.g., a source terminal) coupled to the power line L1, a second terminal (e.g., a drain terminal) coupled to the second terminal of the transistor TN3, and a control terminal (a gate terminal). That is, the transistor TP5 is arranged between the transistor TN3 and the power line L1. The transistor TN5 includes a first terminal (e.g., a drain terminal) coupled to the first terminal of the transistor TN3 (i.e., the node N3), a second terminal (e.g., a source terminal) coupled to the power line L2, and a control terminal (a gate terminal). That is, the transistor TN5 is arranged between the transistor TN3 and the power line L2.

The control terminals of the transistors TP4, TP5, TN4 and TN5 are coupled to the input terminal Ti, which is supplied with the input signal Vin. In this first embodiment, the transistor TP1 is an example of the first P-channel MOS transistor and the transistor TP2 is an example of the second P-channel MOS transistor. The transistor TP3 is an example of the fourth P-channel MOS transistor, the transistor TP4 is an example of the third P-channel MOS transistor, and the transistor TP5 is an example of the fifth P-channel MOS transistor. The transistor TN1 is an example of the first N-channel MOS transistor, the transistor TN2 is an example of the second N-channel MOS transistor, the transistor TN3 is an example of the fourth N-channel MOS transistor, the transistor TN4 is an example of the third N-channel MOS transistor, and the transistor TN5 is an example of the fifth N-channel MOS transistor. The node N1 is an example of the second node, the node N2 is an example of the first node, the node N3 is an example of the third node, the power line L1 is an example of the first power line, the power line L2 is an example of the second power line, the voltage VIH is an example of the higher-potential voltage, and the voltage VIL is an example of the lower-potential voltage.

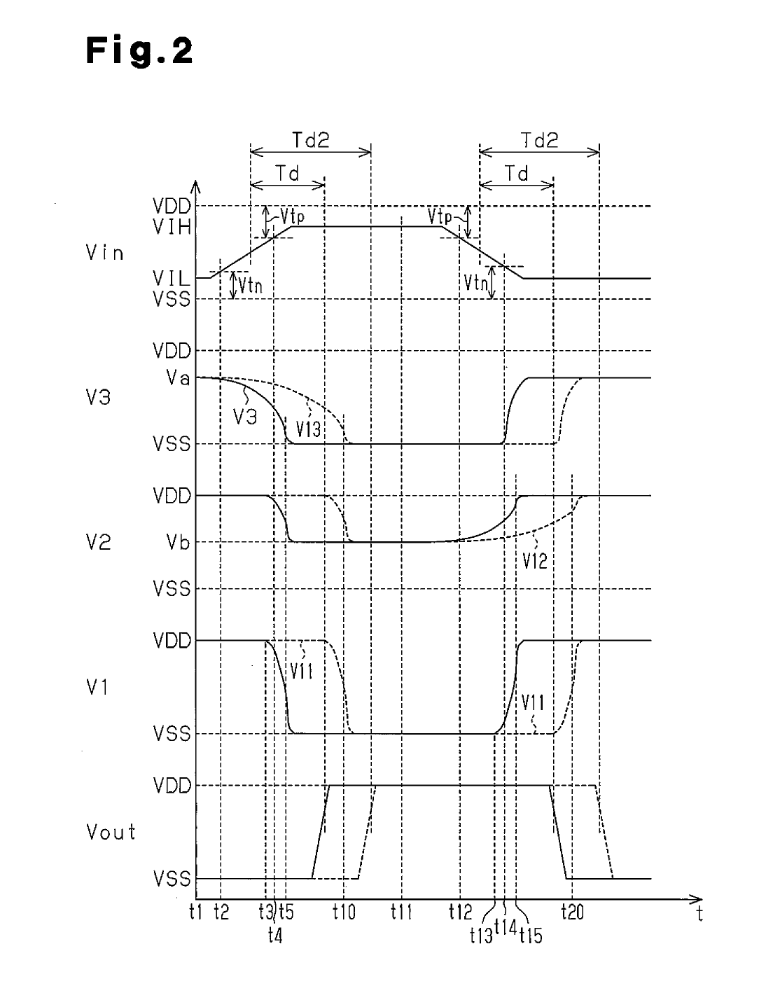

Next, an operation of the input circuit 10 will now be described. In FIG. 2, the vertical and horizontal axes are scaled up and down appropriately for the sake of easy understanding.

First, an operation of the input circuit 10 (in particular, the control circuit 15) when the input signal Vin rises from the VIL level (L level) to the VIH level (H level) will now be described.

At time t1 illustrated in FIG. 2, that is, when the input signal Vin is at the VIL level, the transistors TP1 and TP2 are activated, while the transistors TN1 and TN2 are inactivated. Therefore, the voltage at the node N1, that is, the output signal V1 of the inverter circuit 11 corresponds to the VDD level (H level). The inverter circuit 12 inversely amplifies the output signal V1 of the VDD level to generate an output signal Vout of the VSS level (L level). At this time, in the hysteresis setting circuit 13, the output signal V1 of the VDD level puts the transistor TN3 in an activated state, while the output signal V1 of the VDD level puts the transistor TP3 in an inactivated state. In the deactivation circuit 14, the input signal Vin of the VIL level puts the transistors TN4 and TN5 in an inactivated state, while the input signal Vin of the VIL level puts the transistors TP4 and TP5 in an activated state. In this example, however, the L level (VIL level) of the input signal Vin is higher than the VSS level. In this case, the input signal Vin of the L level may not inactivate the transistor TN2 completely. This causes the voltage V3 at the node N3 to be a divided voltage value depending on the resistive components of the transistors TN2, TN3 and TP5 at time t1. Defining the resistive components of the transistors TN2, TN3 and TP5, respectively, as Rtn2, Rtn3 and Rtp5, the voltage value Va of the voltage V3 at time t1 is obtained as follows:

$$\begin{matrix}Equation 1 & \\ Va = \frac{Rtn 2}{Rtn 2 + Rtn 3 + Rtp 5} \times ( VDD - VSS ) & ( 1 )\end{matrix}$$

Here, when the L level of the input signal Vin equals the VSS level, the input signal Vin of the L level inactivates the transistor TN2 completely. As a result, the voltage value Va of the voltage V3 is obtained as a voltage lower than the high-potential power supply voltage VDD by the threshold voltage Vtn of the transistor TN3 (VDD-Vtn). That is, when the input signal Vin has the level of the low-potential power supply voltage VSS, the control circuit 15 sets the voltage V3 at the node N3 to be lower than the high-potential power supply voltage VDD by the threshold voltage of the N-channel MOS transistor.

Next, when the input signal Vin transits from the VIL level to the VIH level, the transistors TP1, TP2, TN1 and TN2 of the inverter circuit 11 switch between activated and inactivated states. At the beginning of the rise of the input signal Vin (see time t2), the output signal V1 of the VDD level maintains the transistor TN3 in the activated state, and the input signal Vin, which has a level near the VIL level, maintains the transistor TP5 in the activated state. These activated states of the transistors TN3 and TP5 maintain the voltage V3 at the node N3 at the divided voltage value depending on the resistive components Rtn2, Rtn3 and Rtp5 of the respective transistors TN2, TN3 and TP5. This suppresses a decrease in the voltage V3 at the node N3 to the VSS level. Since the transistor TN3 is thus maintained in the activated state at the rise of the input signal Vin, the hysteresis characteristic of the input circuit 10 may be maintained. At the rise of the input signal Vin, the output signal V1 of the VDD level maintains the transistor TP3 in an inactivated state.

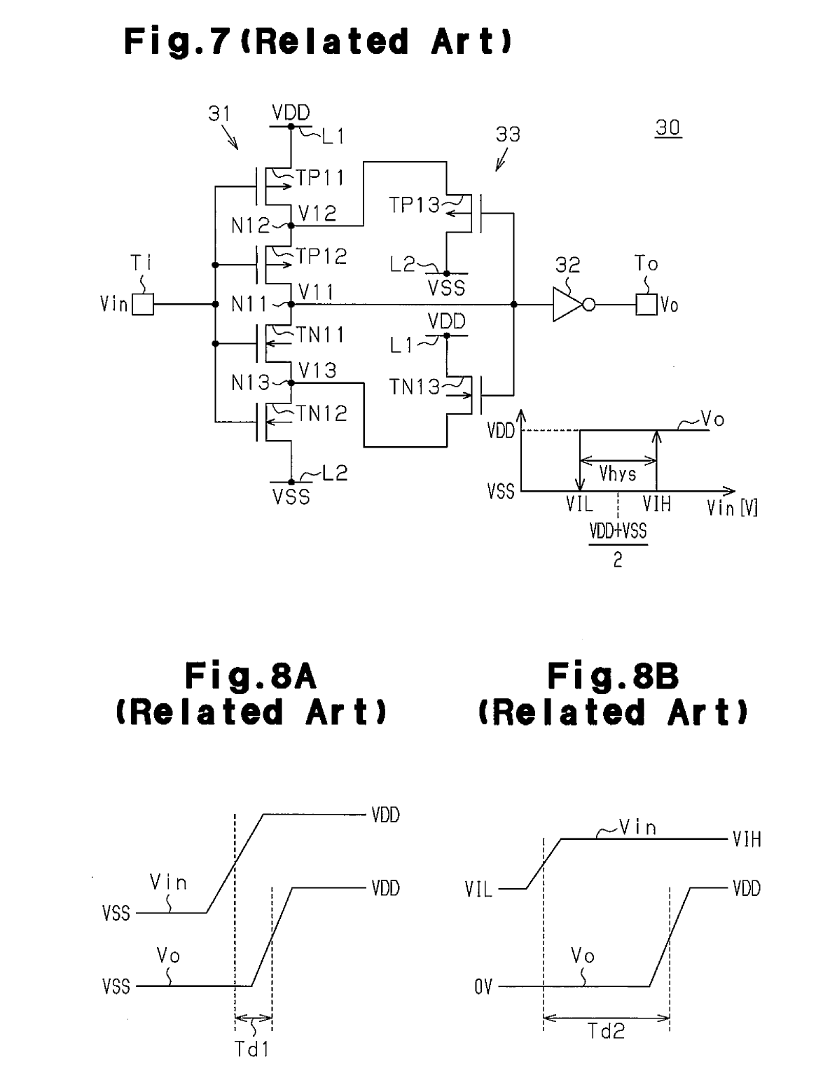

Here, in the input circuit 30 with an absence of the deactivation circuit 14 (see FIG. 7), when the gate voltage of the transistor TN12 (input signal Vin) increases (after time t2 in FIG. 2), charges at the node N13 are discharged to the power line L2 via the transistor TN12. The voltage V13 at the node N13 then decreases to activate the transistor TN12 gradually. At this time, since the voltage VIH is at a level lower than the high-potential power supply voltage VDD (VIH<VDD), the gate voltage of the transistor TN11 (input signal Vin) is lower than its drain voltage (voltage V11 at the node N11). This causes the transistor TN11 not to be immediately activated compared to the case where the H level of the input signal Vin equals the VDD level. Accordingly, the voltage V13 decreases slowly (see the dashed waveform in FIG. 2), whereby it takes a lot of time for the transistor TN11 to be completely activated (at time t10). As a result, it takes a lot of time for the voltage V11 at the node N11 to decrease to the VSS level, and the activated state of the transistor TN13 is maintained over a long period of time. The resistive component of the transistor TN13 thus further serves to suppress a decrease in the voltage V13 at the node N13, that is, further slows down the decrease in the voltage V13. In this manner, after the start of the rise of the input signal Vin (the start of the transition of the signal level), it takes a lot of time for the voltage V13 to decrease to the VSS level, and thereby it also takes a lot of time for the voltage V11 to transit to the VSS level.

On the other hand, in the input circuit 10, the transistors TP5 and TN5 of the deactivation circuit 14 monitors the input signal Vin. Then, when the input signal Vin exceeds a given threshold value, the transistor TN5 is activated and the voltage V3 at the node N3 rapidly decreases. That is, when the voltage level of the input signal Vin, which is applied to the gate terminals of the transistors TN4 and TN5, increases and the potential difference between the input signal Vin and the low-potential power supply voltage VSS becomes higher than the threshold voltage Vtn of the transistors TN4 and TN5, the transistors TN4 and TN5 are activated (see time t2). This causes the node N3 to be coupled to the power line L2 through the transistor TN5 in the activated state and thereby the voltage V3 at the node N3 to decrease rapidly. In this manner, when the input signal Vin exceeds the given threshold value, the transistor TN5 is activated and thereby the function of the transistor TN3 (the hysteresis setting circuit 13) is deactivated. That is, the transistor TN3 (the hysteresis setting circuit 13) is electrically decoupled (cut off) from the inverter circuits 11 and 12. This allows the voltage V3 at the node N3 to decrease rapidly to the VSS level. Therefore, the time from when the input signal Vin starts to rise to when the voltage V3 decreases to the VSS level may be significantly shortened compared to the conventional circuit operation (see the dashed waveform in FIG. 2).

In addition, when the transistor TN2 is completely activated with the decrease in the voltage V3 and the increase in the voltage of the input signal Vin, charges start to move from the node N1 to the node N3 via the transistor TN1. The voltage V1 at the node N1 then starts to decrease at time t3 to activate the transistor TN1 gradually. Further, when the voltage V1 decreases, the transistor TP3 is activated and thereafter the transistor TN3 is inactivated.

In parallel with the operation described above, when the voltage level of the input signal Vin further increases after time t2 and the potential difference between the input signal Vin and the high-potential power supply voltage VDD becomes lower than the threshold voltage Vtp of the transistors TP4 and TP5, the transistors TP4 and TP5 are inactivated (see time t4). When the transistor TP5 is inactivated, the supply of the high-potential power supply voltage VDD to the transistor TN3 is stopped. This causes the function of the transistor TN3 (the hysteresis setting circuit 13) to be completely deactivated.

Subsequently, when the voltage V3 at the node N3 decreases to near the VSS level with the activation of the transistor TN5, the transistor TN1 is completely activated (see time t5). This causes the voltage V1 at the node N1 to decrease rapidly to the VSS level. When the voltage V1 decreases to the VSS level, the output signal Vout of the inverter circuit 12 transits from the VSS level to the VDD level. That is, the level of the output signal Vout is inverted.

In this manner, after the input signal Vin transits from the VIL level to the VIH level, the voltage V3 at the node N3 rapidly decreases to the VSS level. Thus, the input signal Vin of the VIH level may activate the transistor TN1 rapidly. That is, since the voltage V3 at the node N3 (i.e., the drain voltage of the transistor TN1) rapidly decreases to the VSS level even when the level (VIH level) of the input signal Vin applied to the gate terminal of the transistor TN1 is lower than the VDD level, the transistor TN1 is rapidly activated. Further, since the transistor TN1 is rapidly activated, the level of the output signal Vout is also inverted rapidly. The time from the rising edge of the input signal Vin to the rising edge of the output signal Vout, that is, the signal propagation delay time Td may therefore be significantly shortened compared to the signal propagation delay time Td2 in the input circuit 30 (see FIG. 7).

Next, an operation of the input circuit 10 (in particular, the control circuit 15) when the input signal Vin falls from the VIH level (H level) to the VIL level (L level) will now be described.

At time t11 illustrated in FIG. 2, that is, when the input signal Vin is at the VIH level, the transistors TP1 and TP2 are inactivated, while the transistors TN1 and TN2 are activated. Therefore, the output signal V1 of the inverter circuit 11 corresponds to the VSS level. The inverter circuit 12 inversely amplifies the output signal V1 of the VSS level to generate an output signal Vout of the VDD level. At this time, in the hysteresis setting circuit 13, the output signal V1 of the VSS level puts the transistor TN3 in an inactivated state, while the output signal V1 of the VSS level puts the transistor TP3 in an activated state. In the deactivation circuit 14, the input signal Vin of the VIH level puts the transistors TN4 and TN5 in an activated state, while the input signal Vin of the VIH level puts the transistors TP4 and TP5 in an inactivated state. In this example, however, the H level (VIH level) of the input signal Vin is lower than the VDD level. In this case, the input signal Vin of the H level may not inactivate the transistor TP1 completely. This causes the voltage V2 at the node N2 to be a divided voltage value depending on the resistive components of the transistors TP1, TP3 and TN4 at time t11. Defining the resistive components of the transistors TP1, TP3 and TN4, respectively, as Rtp1, Rtp3 and Rtn4, the voltage value Vb of the voltage V2 at time t11 is obtained as follows:

$$\begin{matrix}Equation 2 & \\ Vb = \frac{Rtp 3 + Rtn 4}{Rtp 1 + Rtp 3 + Rtn 4} \times ( VDD - VSS ) & ( 2 )\end{matrix}$$

Here, when the H level of the input signal Vin equals the VDD level, the input signal Vin of the H level inactivates the transistor TP1 completely. As a result, the voltage value Vb of the voltage V2 is obtained as a voltage higher than the low-potential power supply voltage VSS by the threshold voltage Vtp of the transistor TP3 (VSS+Vtp). That is, when the input signal Vin has the level of the high-potential power supply voltage VDD, the control circuit 15 sets the voltage V2 at the node N2 to be higher than the low-potential power supply voltage VSS by the threshold voltage of the P-channel MOS transistor.

Next, when the input signal Vin transits from the VIH level to the VIL level (see after time t12), the transistors TP1, TP2, TN1 and TN2 of the inverter circuit 11 switch between activated and inactivated states. At the beginning of the fall of the input signal Vin (see time t12), the output signal V1 of the VSS level maintains the transistor TP3 in the activated state, and the input signal Vin, which has a level near the VIH level, maintains the transistor TN4 in the activated state. These activated states of the transistors TP3 and TN4 maintain the voltage V2 at the node N2 at the divided voltage value depending on the resistive components Rtp1, Rtp3 and Rtn4 of the respective transistors TP1, TP3 and TN4. This suppresses an increase in the voltage V2 at the node N2 to the VDD level. Since the transistor TP3 is thus maintained in the activated state at the fall of the input signal Vin, the hysteresis characteristic of the input circuit 10 may be maintained. At the fall of the input signal Vin, the output signal V1 of the VSS level maintains the transistor TN3 in an inactivated state.

Here, in the input circuit 30 with an absence of the deactivation circuit 14 (see FIG. 7), when the gate voltage of the transistor TP11 (input signal Vin) decreases (after time t12 in FIG. 2), charges start to move from the power line L1 to the node N12 via the transistor TP11. The voltage V12 at the node N12 then increases to activate the transistor TP11 gradually. At this time, since the voltage VIL is at a level higher than the low-potential power supply voltage VSS (VIL>VSS), the potential difference between the gate voltage of the transistor TP12 (input signal Vin) and the source voltage (voltage V12 at the node N12) is smaller than in the case where the L level of the input signal Vin equals the VSS level. This causes the transistor TP12 not to be immediately activated compared to the case where the L level of the input signal Vin equals the VSS level. Accordingly, the voltage V12 increases slowly (see the dashed waveform in FIG. 2), whereby it takes a lot of time for the transistor TP12 to be completely activated (at time t20). As a result, it takes a lot of time for the voltage V11 at the node N11 to increase to the VDD level, and the activated state of the transistor TP13 is maintained over a long period of time. The resistive component of the transistor TP13 thus further serves to suppress an increase in the voltage V12 at the node N12, that is, further slows down the increase in the voltage V12. In this manner, after the start of the fall of the input signal Vin (the start of the transition of the signal level), it takes a lot of time for the voltage V12 to increase to the VDD level, and thereby it also takes a lot of time for the voltage V11 to transit to the VSS level.

On the other hand, in the input circuit 10, the transistors TP4 and TN4 of the deactivation circuit 14 monitors the input signal Vin. Then, when the input signal Vin exceeds a given threshold value, the transistor TP4 is activated and the voltage V2 at the node N2 increases rapidly. That is, when the voltage level of the input signal Vin, which is applied to the gate terminals of the transistors TP4 and TP5, decreases and the potential difference between the input signal Vin and the high-potential power supply voltage VDD becomes higher than the threshold voltage Vtp of the transistors TP4 and TP5, the transistors TP4 and TP5 are activated (see time t12). This causes the node N2 to be coupled to the power line L1 through the transistor TP4 in the activated state and thereby the voltage V2 at the node N2 to increase rapidly. In this manner, when the input signal Vin thus exceeds the given threshold value, the transistor TP4 is activated and thereby the function of the transistor TP3 (the hysteresis setting circuit 13) is deactivated. That is, the transistor TP3 (the hysteresis setting circuit 13) is electrically decoupled (cut off) from the inverter circuits 11 and 12. This allows the voltage V2 at the node N2 to increase rapidly to the VDD level. Therefore, the time from when the input signal Vin starts to fall to when the voltage V2 increases to the VDD level may be significantly shortened compared to the conventional circuit operation (see the dashed waveform in FIG. 2).

In addition, when the transistor TP1 is completely activated with the increase in the voltage V2 and the decrease in voltage of the input signal Vin, charges start to move from the node N2 to the node N1 via the transistor TP2. The voltage V1 at the node N1 then starts to increase at time t13 to activate the transistor TP2 gradually. Further, when the voltage V1 increases, the transistor TN3 is activated and thereafter the transistor TP3 is inactivated.

In parallel with the operation described above, when the voltage level of the input signal Vin further decreases after time t12 and the potential difference between the input signal Vin and the low-potential power supply voltage VSS becomes lower than the threshold voltage Vtn of the transistors TN4 and TN5, the transistors TN4 and TN5 are inactivated (see time t14). When the transistor TN4 is inactivated, the supply of the low-potential power supply voltage VSS to the transistor TP3 is stopped. This causes the function of the transistor TP3 (the hysteresis setting circuit 13) to be completely deactivated.

Subsequently, when the voltage V2 at the node N2 increases to near the VDD level with the activation of the transistor TP4, the transistor TP2 is completely activated (see time t15). This causes the voltage V1 at the node N1 to increase rapidly to the VDD level. When the voltage V1 increases to the VDD level, the output signal Vout of the inverter circuit 12 transits from the VDD level to the VSS level. That is, the level of the output signal Vout is inverted.

In this manner, after the input signal Vin transits from the VIH level to the VIL level, the voltage V2 at the node N2 increases rapidly to the VDD level. Thus, the input signal Vin of the VIL level may activate the transistor TP2 rapidly. That is, since the voltage V2 at the node N2 (i.e., the source voltage of the transistor TP2) increases rapidly to the VDD level even when the level (VIL level) of the input signal Vin applied to the gate terminal of the transistor TP2 is higher than the VSS level, the transistor TP2 is rapidly activated. Further, since the transistor TP2 is rapidly activated, the level of the output signal Vout is also inverted rapidly. The time from the falling edge of the input signal Vin to the falling edge of the output signal Vout, that is, the signal propagation delay time Td may therefore be significantly shortened compared to the signal propagation delay time Td2 in the input circuit 30 (see FIG. 7).

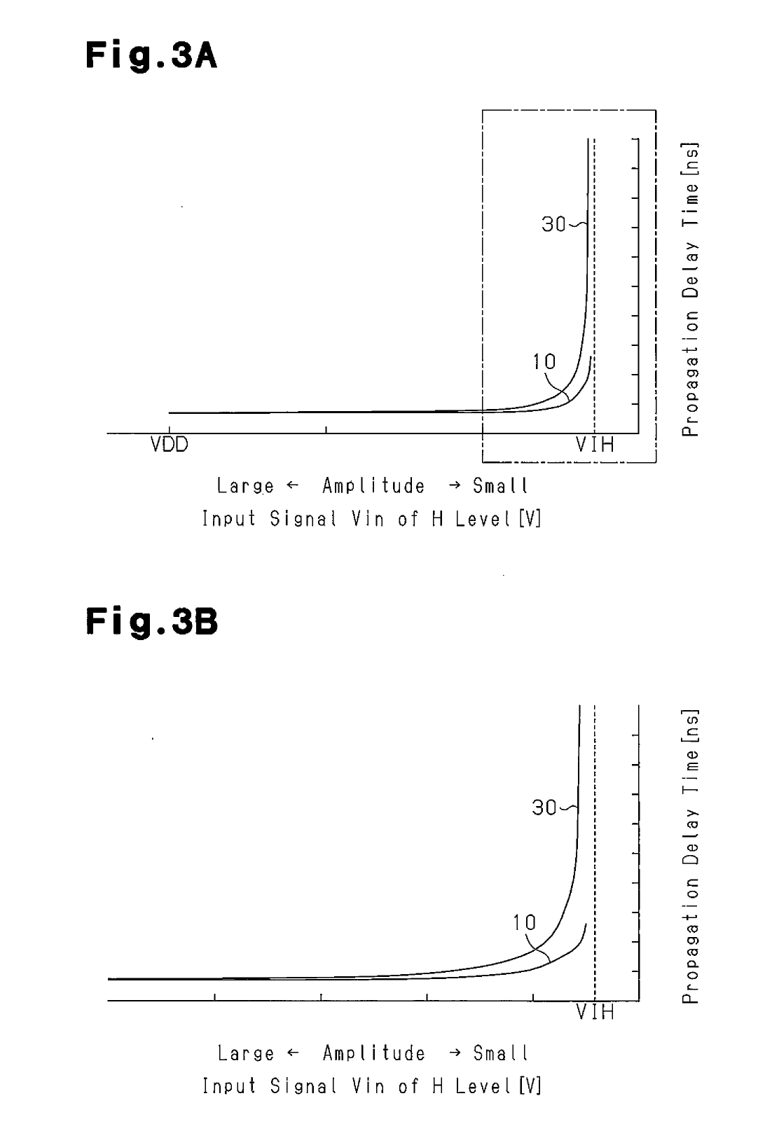

FIGS. 3A and 3B illustrate simulation results of the change in the signal propagation delay time when the amplitude of the input signal Vin changes in the input circuit 10 illustrated in FIG. 1 and the input circuit 30 illustrated in FIG. 7. In FIGS. 3A and 3B, the L level of the input signal Vin is fixed to the VSS level, while the H level of the input signal Vin is changed from the VDD level to the VIH level in the input circuits 10 and 30. In FIGS. 3A and 3B, the horizontal axis represents the voltage level of the input signal Vin of the H level and the vertical axis represents the signal propagation delay time in the input circuits 10 and 30. FIG. 3B is an enlarged view illustrating the simulation result within the dashed line frame in FIG. 3A.

As is apparent from FIGS. 3A and 3B, the lower the voltage level of the input signal Vin of the H level, that is, the smaller the amplitude of the input signal Vin, the longer the signal propagation delay time becomes. However, the signal propagation delay time fluctuates (increases) more slowly in the input circuit 10 than in the input circuit 30. With a fluctuation in the amplitude of the input signal Vin, the input circuit 10 provided with the deactivation circuit 14 undergoes a smaller fluctuation in the signal propagation delay time than the input circuit 30 (FIG. 7) with an absence of the deactivation circuit 14. That is, in the input circuit 10, the difference is small between the signal propagation delay time when the H level of the input signal Vin equals the VDD level (the input signal Vin has a larger amplitude) and the signal propagation delay time when the H level of the input signal Vin equals a level near the VIH level (the input signal Vin has a smaller amplitude). Accordingly, even when the input signal Vin has a smaller amplitude, it is possible in the input circuit 10 to suppress an increase in the signal propagation delay time.

The first embodiment has the advantages described below.

(1) When the input signal Vin exceeds a given threshold value, the transistors TP4 and TP5 or the transistors TN4 and TN5 of the deactivation circuit 14 are activated and thereby the function of the hysteresis setting circuit 13 is deactivated. With the activation of the transistors TP4 and TN5, the voltage V3 at the node N3 rapidly decreases at the rise of the input signal Vin, while the voltage V2 at the node N2 rapidly decreases at the fall of the input signal Vin. Accordingly, even when the input signal Vin has a smaller amplitude, the transistor TN1 is rapidly activated at the rise of the input signal Vin, while the transistor TP2 is rapidly activated at the fall of the input signal Vin. The signal propagation delay time may therefore be significantly shortened when the input signal Vin has a smaller amplitude, compared to the input circuit 30 (see FIG. 7).

(2) The signal propagation delay time undergoes a small fluctuation with a fluctuation in the amplitude of the input signal Vin. Thus, even when the input signal Vin has a smaller amplitude, it is possible to suitably suppress an increase in the signal propagation delay time Td. Accordingly, even when the input signal Vin has a smaller amplitude, it is possible to suppress a fluctuation in the signal propagation delay time Td without changing the level of the threshold voltage VIH or VIL (e.g., without decreasing the hysteresis Vhys) of the input circuit 10.

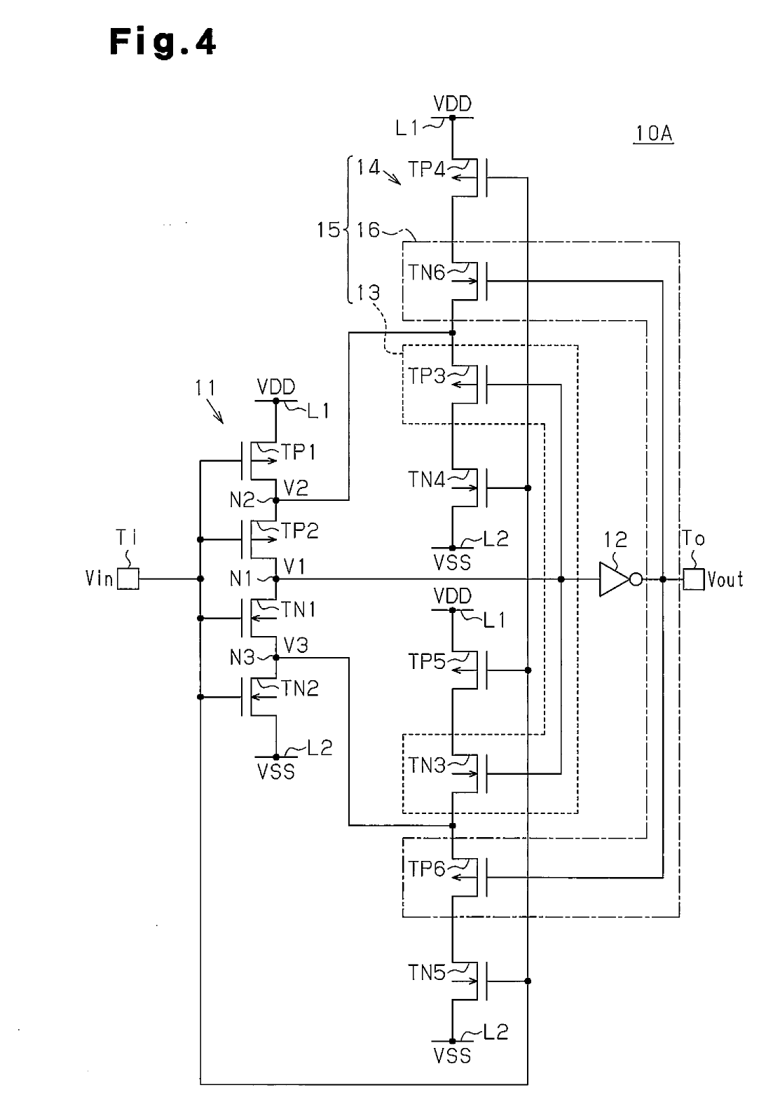

A second embodiment will now be described with reference to FIG. 4. In FIG. 4, components identical to those illustrated in FIG. 1 are designated by the same reference symbols to omit the detailed description thereof. Differences from the first embodiment will now be mainly described.

As illustrated in FIG. 4, an input circuit 10A includes the inverter circuit 11, the inverter circuit 12, and the control circuit 15. The control circuit 15 includes the hysteresis setting circuit 13, the deactivation circuit 14, and a through-current prevention circuit 16.

The through-current prevention circuit 16 includes an N-channel MOS transistor TN6 and a P-channel MOS transistor TP6.

The transistor TN6 includes a first terminal (e.g., a drain terminal) coupled to the second terminal (e.g., a drain terminal) of the transistor TP4 of the deactivation circuit 14, a second terminal (e.g., a source terminal) coupled to the node N2 and the first terminal (e.g., a source terminal) of the transistor TP3 of the hysteresis setting circuit 13, and a control terminal (a gate terminal). That is, the transistor TN6 is arranged between the node N2 and the transistor TP4.

The transistor TP6 includes a first terminal (e.g., a source terminal) coupled to the node N3 and the first terminal (e.g., a source terminal) of the transistor TN3 of the hysteresis setting circuit 13, a second terminal (e.g., a drain terminal) coupled to the first terminal (e.g., a drain terminal) of the transistor TN5 of the deactivation circuit 14, and a control terminal (a gate terminal). That is, the transistor TP6 is arranged between the node N3 and the transistor TN5.

The control terminals of the transistors TN6 and TP6 are coupled to the output terminal To. That is, the output signal Vout of the inverter circuit 12 is supplied to the control terminals of the transistors TN6 and TP6.

In this second embodiment, the transistor TN6 is an example of the sixth N-channel MOS transistor and the transistor TP6 is an example of the sixth P-channel MOS transistor.

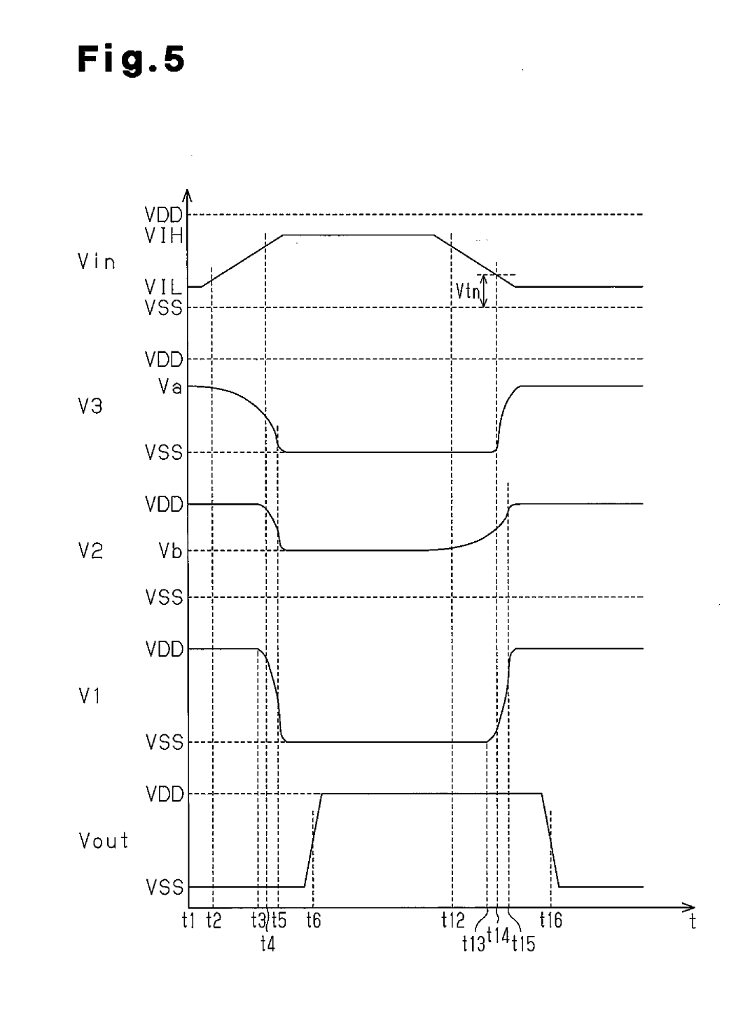

Next, an operation of the input circuit 10A (in particular, the through-current prevention circuit 16) will now be described with reference to FIGS. 4 and 5. Here, an operation of the input circuit 10A in the case where the input signal Vin rises from the VIL level to the VIH level and then, after a given period of time, the input signal Vin falls from the VIH level to the VIL level will be described. The circuit operation except for the through-current prevention circuit 16 (transistors TN6 and TP6) is the same as in the first embodiment and it will not be described here in detail. In FIG. 5, the vertical and horizontal axes are scaled up and down appropriately for the sake of easy understanding.

At time t2 illustrated in FIG. 5, the input signal Vin starts to rise. When the potential difference between the input signal Vin and the low-potential power supply voltage VSS becomes higher than the threshold voltage Vtn of the transistor TN5, the transistor TN5 is activated. At this time, the output signal Vout of the VSS level puts the transistor TP6 of the through-current prevention circuit 16 in an activated state. This causes the node N3 to be coupled to the power line L2 through the transistors TP6 and TN5 in the activated state. Accordingly, as in the input circuit 10 described above, the voltage V3 at the node N3 rapidly decreases to the VSS level to activate the transistor TN1 rapidly. As a result, the output signal Vout transits rapidly from the VSS level to the VDD level. This suppresses an increase in the signal propagation delay time.

Subsequently, when the output signal Vout rises and the potential difference between the output signal Vout and the high-potential power supply voltage VDD becomes lower than the threshold voltage Vtp of the transistor TP6, the transistor TP6 is inactivated (see time t6). At this time, the transistors TN1, TN5 and TN6 are in an activated state, while the transistors TP2 and TP4 are in an inactivated state. The voltage V3 at the node N3 equals the VSS level and the voltage V2 at the node N2 has the voltage value Vb described above.

Thereafter, when the input signal Vin falls from the VIH level to the VIL level and the potential difference between the input signal Vin and the high-potential power supply voltage VDD becomes higher than the threshold voltage Vtp of the transistor TP4, the transistor TP4 is activated (see time t12). At this time, the output signal Vout of the VDD level puts the transistor TN6 of the through-current prevention circuit 16 in an activated state, and the node N2 is coupled to the power line L1 through the transistors TN6 and TP4 in the activated state. Accordingly, as in the input circuit 10 described above, the voltage V2 at the node N2 increases rapidly to the VDD level to activate the transistor TP2 rapidly. As a result, the output signal Vout transits rapidly from the VDD level to the VSS level. This suppresses an increase in the signal propagation delay time.

At time T12, the output signal Vout of the VDD level puts the transistor TP6 of the through-current prevention circuit 16 in an inactivated state. Thereafter, the transistor TP1 is completely activated with the increase in the voltage V2 and the decrease in voltage of the input signal Vin. When the transistor TP1 is activated, charges start to move from the node N2 to the node N1 via the transistor TP2 (see time t13). The voltage V1 at the node N1 then increases to activate the transistor TP2 gradually. At this time, since the potential difference between the input signal Vin and the low-potential power supply voltage VSS is higher than the threshold voltage Vtn of the transistors TN1 and TN5, the transistors TN1 and TN5 are maintained in the activated state. That is, since the voltage V2 at the node N2 starts to rise from the voltage value Vb, the transistor TP2 may be activated before the transistor TN1 switches from an activated state to an inactivated state.

Here, in the input circuit 10 (see FIG. 1) of the first embodiment, the transistors TP4, TP2, TN1 and TN5 are activated at time t13. This causes a through-current to flow from the power line L1 to the power line L2 through the transistors TP4, TP2, TN1 and TN5 in the activated state. The through-current continues to flow until the potential difference between the input signal Vin and the low-potential power supply voltage VSS becomes lower than the threshold voltage Vtn of the transistor TN1 so that the transistor TN1 is shifted to an inactivated state (see time t13 to t14).

On the other hand, in the input circuit 10A of this second embodiment, the transistors TP4, TP2, TN1 and TN5 are activated at time t13, while the output signal Vout of the VDD level puts the transistor TP6 of the through-current prevention circuit 16 in an inactivated state. This suppresses a through-current from flowing from the power line L1 toward the power line L2. Thereafter, when the output signal Vout falls and the potential difference between the output signal Vout and the low-potential power supply voltage VSS becomes lower than the threshold voltage Vtn of the transistor TN6, the transistor TN6 is shifted from the activated state to an inactivated state (see time t16).

Similarly, at the rise of the input signal Vin, the output signal Vout of the VSS level puts the transistor TN6 of the through-current prevention circuit 16 in an inactivated state during the period in which both the transistors TP2 and TN1 are activated (see time t3 to t4, for example). Thus, also at the rise of the input signal Vin, the inactivation of the transistor TN6 suppresses a through-current from flowing from the power line L1 toward the power line L2.

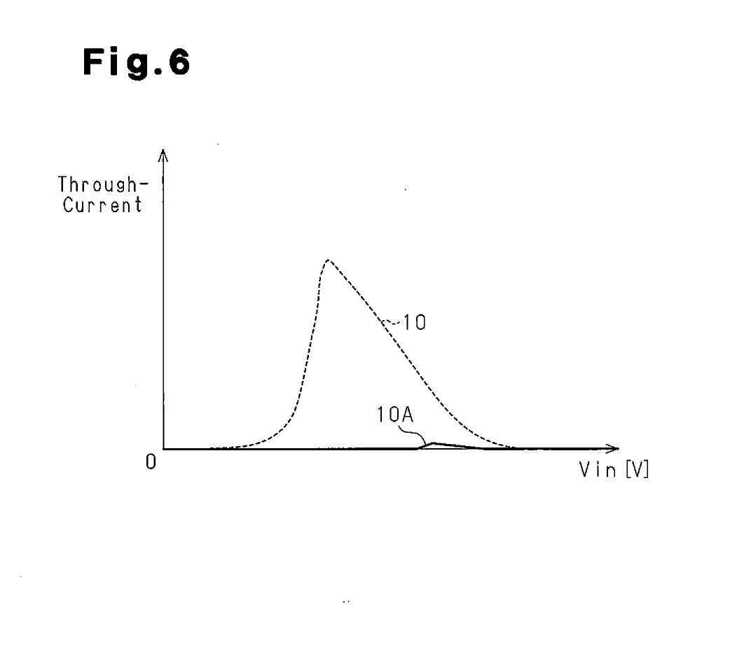

As illustrated in FIG. 6, when compared to the input circuit 10, the through-current prevention circuit 16 reduces a through-current flowing from the power line L1 toward the power line L2. However, as illustrated in FIG. 6, a through-current flows slightly even in the input circuit 10A. This is for the reason that at the rise of the input signal Vin, a through-current flows from the power line L1 to the power line L2 through the transistors TP5, TN3, TP6 and TN5 and, at the fall of the input signal Vin, a through-current flows from the power line L1 to the power line L2 through the transistors TP4, TN6, TP3 and TN4.

In addition to the advantages (1) and (2) in the first embodiment, the second embodiment has the advantages described below.

(3) The through-current prevention circuit 16 (transistors TN6 and TP6) is arranged along the path from the power line L1 to the power line L2 through the transistors TP4, TP2, TN1 and TN5. The through-current prevention circuit 16 suppresses a through-current flowing from the power line L1 to the power line L2 through the transistors TP4, TP2, TN1 and TN5. This reduces the consumption current in the input circuit 10A.

It should be apparent to those skilled in the art that the above embodiment may be embodied in many other specific forms without departing from the scope of the invention. Particularly, it should be understood that the above embodiment may be embodied in the following forms.

In the above-described embodiments, the signal fed back to the gate terminals of the transistors TP3 and TN3 of the hysteresis setting circuit 13 is not limited to the output signal V1 of the inverter circuit 11, but may be, for example, the output signal Vout of the inverter circuit 12. In this case, the transistor TP3 is replaced with an N-channel MOS transistor and the transistor TN3 is replaced with a P-channel MOS transistor.

In the above-described embodiments, the transistors TN4 and TP5 of the deactivation circuit 14 may be omitted. Even in this case, at the rise of the input signal Vin, the voltage V3 at the node N3 may decrease rapidly to the VSS level with the activation of the transistor TN5, while at the fall of the input signal Vin, the voltage V2 at the node N2 may increase rapidly to the VDD level with the activation of the transistor TP4. In this case, the second terminal of the transistor TP3 is directly coupled to the power line L2 and the second terminal of the transistor TN3 is directly coupled to the power line L1.

In the above-described embodiments, the control circuit 15, that is, the hysteresis setting circuit 13, the deactivation circuit 14, and the through-current prevention circuit 16 are applied in the input circuits 10 and 10A. Instead, the hysteresis setting circuit 13, the deactivation circuit 14, and the through-current prevention circuit 16 may be applied in an input and output circuit.

In the above-described embodiments, the input circuit employs a non-inverting type, but may employ an inverting type. In this case, odd-numbered inverter circuit stages are arranged, for example, between the inverter circuit 12 and the output terminal To.

All examples and conditional language recited herein are intended for pedagogical purposes to aid the reader in understanding the principles of the invention and the concepts contributed by the inventor to furthering the art, and are to be construed as being without limitation to such specifically recited examples and conditions, nor does the organization of such examples in the specification relate to an illustration of the superiority and inferiority of the invention. Although embodiments of the present invention have been described in detail, it should be understood that various changes, substitutions, and alterations could be made hereto without departing from the spirit and scope of the invention.

1. An input circuit comprising:
a first P-channel MOS transistor including a first terminal coupled to a first power line that is supplied with a high-potential power supply voltage, a second terminal coupled to a first node, and a gate terminal that receives an input signal;
a second P-channel MOS transistor including a first terminal coupled to the first node, a second terminal coupled to a second node, and a gate terminal that receives the input signal;
a first N-channel MOS transistor including a first terminal coupled to the second node, a second terminal coupled to a third node, and a gate terminal that receives the input signal;
a second N-channel MOS transistor including a first terminal coupled to the third node, a second terminal coupled to a second power line that is supplied with a low-potential power supply voltage lower than the high-potential power supply voltage, and a gate terminal that receives the input signal; and
a control circuit that controls the potential at the first node and the potential at the third node based on the input signal and the potential at the second node.

2. The input circuit according to claim 1, wherein the control circuit includes:
a third P-channel MOS transistor including a first terminal coupled to the first power line, a second terminal coupled to the first node, and a gate terminal that receives the input signal;
a fourth P-channel MOS transistor including a first terminal coupled to the first node, a second terminal, and a gate terminal coupled to the second node;
a third N-channel MOS transistor including a first terminal coupled to the second terminal of the fourth P-channel MOS transistor, a second terminal coupled to the second power line, and a gate terminal that receives the input signal;
a fifth P-channel MOS transistor including a first terminal coupled to the first power line, a second terminal, and a gate terminal that receives the input signal;
a fourth N-channel MOS transistor including a first terminal coupled to the third node, a second terminal coupled to the second terminal of the fifth P-channel MOS transistor, and a gate terminal coupled to the second node; and
a fifth N-channel MOS transistor including a first terminal coupled to the third node, a second terminal coupled to the second power line, and a gate terminal that receives the input signal.

3. The input circuit according to claim 1, further comprising an inverter circuit including an input terminal coupled to the second node and an output terminal, wherein the control circuit includes:
a third P-channel MOS transistor including a first terminal coupled to the first power line, a second terminal, and a gate terminal that receives the input signal;
a sixth N-channel MOS transistor including a first terminal coupled to the second terminal of the third P-channel MOS transistor, a second terminal coupled to the first node, and a gate terminal coupled to the output terminal of the inverter circuit;
a fourth P-channel MOS transistor including a first terminal coupled to the first node, a second terminal, and a gate terminal coupled to the second node;
a third N-channel MOS transistor including a first terminal coupled to the second terminal of the fourth P-channel MOS transistor, a second terminal coupled to the second power line, and a gate terminal that receives the input signal;
a fifth P-channel MOS transistor including a first terminal coupled to the first power line, a second terminal, and a gate terminal that receives the input signal;
a fourth N-channel MOS transistor including a first terminal coupled to the third node, a second terminal coupled to the second terminal of the fifth P-channel MOS transistor, and a gate terminal coupled to the second node;
a sixth P-channel MOS transistor including a first terminal coupled to the third node, a second terminal, and a gate terminal coupled to the output terminal of the inverter circuit; and
a fifth N-channel MOS transistor including a first terminal coupled to the second terminal of the sixth P-channel MOS transistor, a second terminal coupled to the second power line, and a gate terminal that receives the input signal.

4. The input circuit according to claim 1, wherein
the control circuit includes an N-channel MOS transistor and a P-channel MOS transistor,
when the input signal has the level of the low-potential power supply voltage, the control circuit sets the potential at the third node to be lower than the high-potential power supply voltage by a threshold voltage of the N-channel MOS transistor of the control circuit, and
when the input signal has the level of the high-potential power supply voltage, the control circuit sets the potential at the first node to be higher than the low-potential power supply voltage by a threshold voltage of the P-channel MOS transistor of the control circuit.

5. The input circuit according to claim 1, wherein the input signal has an amplitude from a higher-potential voltage, which is lower than the high-potential power supply voltage, to a lower-potential voltage, which is higher than the low-potential power supply voltage and lower than the higher-potential voltage.
